(19) United States
(12) Patent Application Publication
(10) Pub. No.: US 2026/0231349 A1
(43) Pub. Date: Aug. 6, 2026

(54) POWER DISTRIBUTION SYSTEM

(71) Applicant: Microsoft Technology Licensing, LLC, Redmond, WA (US)

(72) Inventors: Robert Craig McFARLANE, JR., Sammamish, WA (US); John Joseph SIEGLER, Carnation, WA (US); Haowei HSU, Mercer Island, WA (US); Brandon DeVAUL, Redmond, WA (US); Banha SOK, Kirkland, WA (US)

(21) Appl. No.: 19/042,765

(22) Filed: Jan. 31, 2025

(51) Int. Cl. H05K 7/14

(52) U.S. Cl. CPC H05K 7/1492; H05K 7/1487

(57) ABSTRACT

The disclosure relates to power distribution systems for Information Technology (IT) racks. For example, a power distribution system may include a sidecar unit that provides flexibility for enhanced power delivery, including High Voltage Direct Current (HVDC) power of at least 400V or more to meet the power demands of modern data centers and other computer facilities. The sidecar unit may also provide backward compatibility with IT racks that use 50V inputs for its components. The power distribution system may include an architecture in which an IT rack includes rack slots that each house a node and a corresponding sidecar unit, which can be released from the node for easy serviceability of the sidecar unit and/or the node. The IT rack may take HVDC power as input from a power rack having power distribution units.

### BACKGROUND

Power demand of computers such as in data centers is growing at an increasing rate. This is in large part due to the rapid expansion of the use of Artificial Intelligence (AI) and machine learning models, which require high computational loads to train and execute. These loads in turn require increasing power demands from computers such as server blades. To save space and manage environmental control, the computers may be stacked in an Information Technology (IT) rack. The IT rack may include a centralized power shelf system that receives AC input power and generates output in the range of 50V for use by the computers (“nodes”). However, as rack power infrastructure evolves to provide increasing amounts of power to support AI and Machine Learning, among other computational tasks, a bottle neck to the rack power infrastructure becomes the power output and thermal performance.

### BRIEF DESCRIPTION OF THE DRAWINGS

Features of the present disclosure may be illustrated by way of example and not limited in the following figure(s), in which like numerals indicate like elements.

FIG. 1A illustrates a rear perspective view of an example of an IT rack and an example of a power rack, according to an implementation.

FIG. 1B illustrates a rear perspective view of an example of an IT rack without the use of a power rack, according to an implementation.

FIG. 2A illustrates a front view of an example IT rack, according to an implementation.

FIG. 2B illustrates a zoomed in front view of a portion of an example IT rack to show additional detail while omitting others for clarity, according to an implementation.

FIG. 2C illustrates a top-down view of an example IT rack to co-location and adjacency of a node and a modular sidecar power distribution unit for improved serviceability, according to an implementation.

FIG. 3 illustrates a top-down view of a rack slot showing an example of a node and a modular sidecar power distribution unit that bridges power from a power distribution bar to the corresponding node in the rack slot, according to an implementation.

FIG. 4 illustrates a top-down view of a rack slot showing an example of a node and a modular sidecar power distribution unit that converts power from a power distribution bar, according to an implementation.

FIG. 5 illustrates a side perspective view of a modular sidecar power distribution unit, according to an implementation.

FIG. 6 illustrates a front elevation view of an example of a sidecar unit coupled to a node, according to an implementation.

FIG. 7 illustrates an example of a sidecar unit with a rack having space limitations that prevent the sidecar unit from being adjacent to a node, according to an implementation.

### DETAILED DESCRIPTION

The disclosure relates to a power distribution system that provides power to nodes in an IT rack. Currently, Graphics Processing Units (GPUs) and other computer components are being increasingly leveraged to train and use AI models, which require high computational loads and correspondingly high power demand. Delivery of power to IT racks in the range of 50V may be insufficient to support power demands greater than 132 KW. However, this ceiling may be too low for increasing power demands and scaling power distribution is problematic. For example, scaling power delivery at voltage in the range of 50V is becoming infeasible due to current loads and corresponding need for more electrically conductive material such as copper. Increasing voltage delivery may alleviate these and other issues. For example, distribution of power in the range of 400V or more reduces current by at least 8-times, reducing the required quantity of electrically conductive material. However, managing power conversion at HVDC (high-voltage direct current) to 50V can be problematic.

The design of the power distribution system may provide individual and/or combined improvements to power distribution systems to address these and other issues. For example, the power distribution system may facilitate scalable power distribution to the nodes. In some examples, the power distribution system may facilitate backward compatibility with conventional rack systems while maintaining flexibility to scale to enhanced power distribution. The design facilitates an ability to grow rack power to at least 1 MW for future AI/GPU racks. The design further provides the flexibility to the node design to accommodate new networking gear and cooling equipment.

In some examples, the power distribution system may facilitate forward compatibility with future power distribution systems. In some examples, the power distribution system may reduce operational cost by enhancing serviceability of power supply devices and/or nodes of an IT rack. In some examples, the power distribution system may enhance isolation of HVDC circuitry and components from conductive fluids.

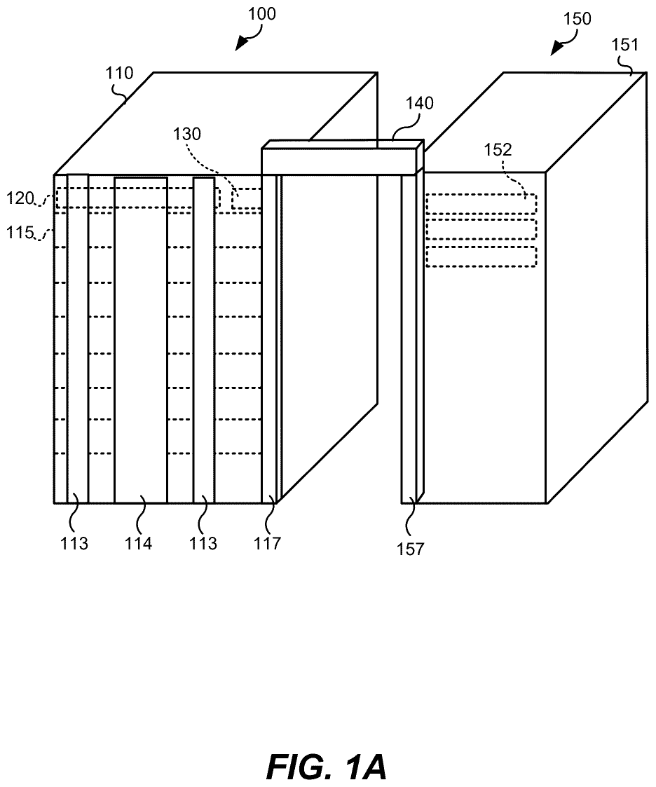

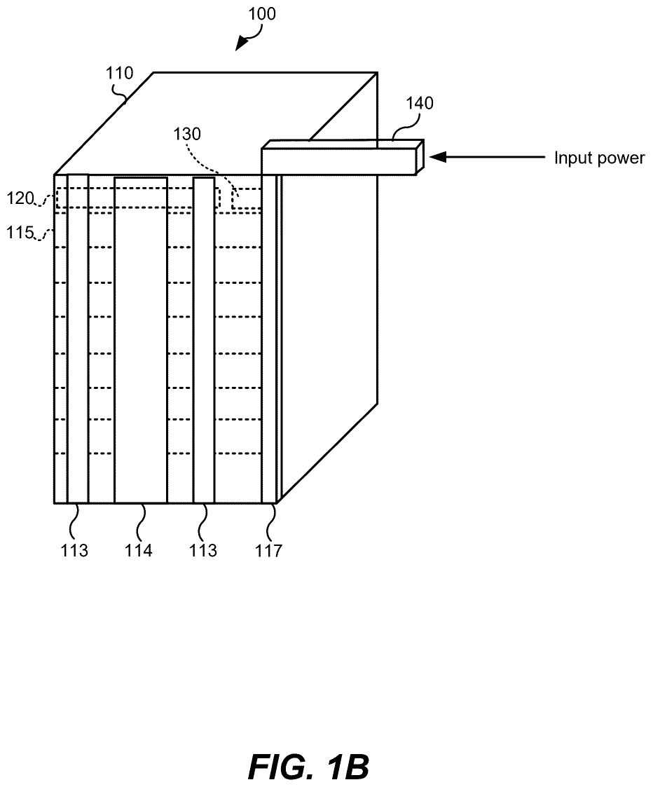

FIG. 1A illustrates rear perspective views of an IT rack 100 and a power rack 50, according to an implementation. As used throughout this disclosure, terms of orientation such as top, upper, front, left side, right side, bottom, lower, and rear are relative terms. Generally speaking, unless otherwise noted, these orientation terms will refer to an orientation of an IT rack 100 or other referenced component as intended to be installed for operation. For example, the front of an IT rack 100 will refer to a side in which components are loaded into the IT rack 100 and the bottom or lower end of the IT rack 100 will refer to the part of the IT rack 100 that is closest to the ground when installed.

The IT rack 100 may include an enclosure body 110. The enclosure body 110 may be made from a rigid material such as cold rolled steel, aluminum, stainless steel, and/or other materials that can suitably house or support the components of the IT rack 100. The enclosure body 110 may house or be coupled to a rack cooling manifold 113, a networking plane 114, a vertical bus bar 117, and/or other components

A rack cooling manifold 113 is a system that distributes a coolant to components within the IT rack 100. The coolant may include a gas, a liquid, and/or other element that can absorb heat from the components. The rack cooling manifold 113 may be part of a passive or active system, in which case a fan, motor, or other device actively moves the coolant through the rack cooling manifold. Although illustrated as including two rack cooling manifolds 113, the IT rack 100 may include other numbers of rack cooling manifolds 113.

A networking plane 114 is a portion of the IT rack 100 that organizes and/or connects networking equipment. For example, the networking plane 114 may house switches, routers, patch panels, cables, and/or other networking equipment.

The enclosure body 110 may be configured to house a plurality of rack slots 115. A rack slot 115 is a portion of the IT rack 100 that can hold equipment. The number of rack slots 115 may vary depending on specific configuration of the IT rack 100. In some examples, the enclosure body 110 may house forty-four rack slots 115, although other numbers of rack slots 115 can be accommodated by increasing or decreasing the size of the IT rack 100.

In some implementations, a rack slot 115 may house a node 120 and a modular sidecar power distribution unit 130 (hereinafter, “sidecar unit 130”). A node 120 is a device that provides computer or networking functionality and can be placed in an IT rack 100. Examples of a node 120 may include, without limitation, a server device, a network device, a storage device, and/or other types of devices that can be housed in an IT rack. A server device may include a server blade or other computing device comprising one or more Central Processing Units (CPUs), one or more Graphical Processing Units (GPUs), solid state drivers (SSDs), and/or other processing units.

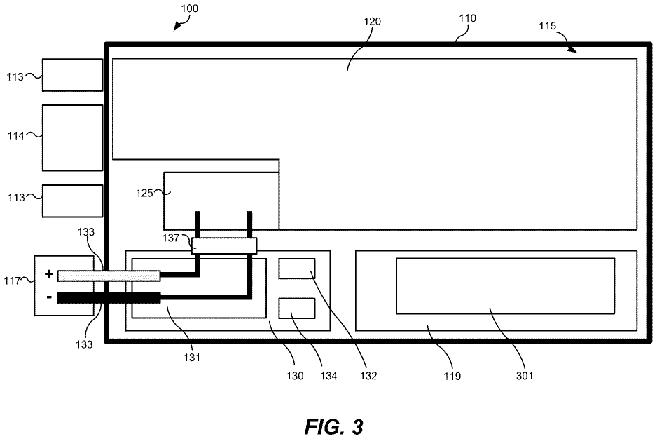

A sidecar unit 130 is a device that receives input power and provides output power to the corresponding node 120. In some examples, the sidecar unit 130 may act as a bridge to transfer the received input power to a corresponding node 120. In some examples, the sidecar unit 130 may transform the input power and provide the transformed power to the corresponding node 120. Examples of the sidecar unit 130 are further illustrated and described with respect to FIGS. 3-6.

In some examples, as illustrated, a sidecar unit 130 is electrically coupled to and receives the input power from a vertical bus bar 117. A vertical bus bar 117 is an electrically conductive material, such as copper, aluminum, steel, and/or other medium that can conduct electricity. In some examples, the vertical bus bar 117 may be at least partially electrically shielded via a sheath that may be non-electrically conductive, such as rubber, fiberglass, ceramic, and/or other material that does not conduct electricity. In some examples, the vertical bus bar 117 may include a sheath that protects against Electromagnetic (EM), physical, or other types damage. In these examples, the sheath may be composed of a metal or metal alloy. The vertical bus bar 117 is shown as a rectangular bar for illustration and not limitation. Other shapes and relative sizes can be used - the figures are not necessarily drawn to scale.

As illustrated, the vertical bus bar 117 is electrically coupled to a voltage distribution bus bar 140. A voltage distribution bus bar 140 is an electrically conductive material, such as copper, aluminum, steel, and/or other material that can conduct electricity. In some examples, the voltage distribution bus bar 140 may be at least partially electrically shielded similar to the shielding of the vertical bus bar 117. The voltage distribution bus bar 140 is shown in the figures as a rectangular bar for illustration and not limitation. Other shapes and relative sizes can be used - the figures are not necessarily drawn to scale.

In some implementations, a voltage distribution bus bar 140 is electrically connected to and receives power from a vertical bus bar 157 of a power rack 50. A vertical bus bar 157 is similar to and may be at least partially shielded the same way as a vertical bus bar 117. A power rack 150 may include an enclosure body 151 configured to house one or more Power Supply Units (PSUs) 152. A PSU 152 may include an AC-to-DC converter that converts input AC power (such as from a facility) into output DC power. The output DC power may be in the range of 400V, 800V, or other voltage. A PSU 152 may provide output DC power to the vertical bus bar 157, which may electrically transmit the output DC power to the voltage distribution bus bar 140. A PSU 152 may alternatively provide AC power.

In some examples, as illustrated, the voltage distribution bus bar 140 may be physically coupled to the rear and upper sides of the IT rack 100 and the power rack 50. This configuration may protect the voltage distribution bus bar 140 against exposure to liquid coolant and/or other contaminants. As also illustrated, two rack cooling manifolds 113, a networking plane 114, and a vertical bus bar 117 are each configured vertically along the height of the IT rack 100 as shown to respectively cool, provide networking connectivity, and power to more than one rack slot 115. However, the particular orientation, placement, and shape of a rack cooling manifold 113, a networking plane 114, and/or a vertical bus bar 117 may vary so long as they can respectively cool, provide networking connectivity, or power to one or more—typically multiple—rack slots 115 and equipment housed therein.

In some examples, an IT rack 100 may receive facility power, such as AC power, directly from a facility. This implementation is illustrated in FIG. 1B, in which case the voltage distribution bus bar 140 receives facility power directly, and not from a power rack 50. In some of these examples, a PSU 152 may be housed in the IT rack 100, such as in a rack slot 115, and coupled to the vertical bus bar 117. IT rack 100 may alternatively or additionally receive DC power from the facility.

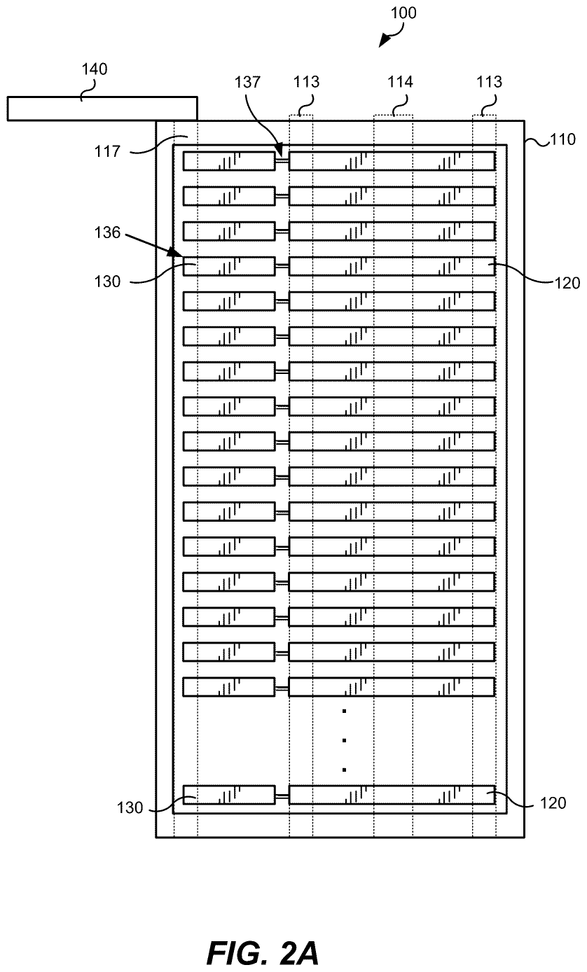

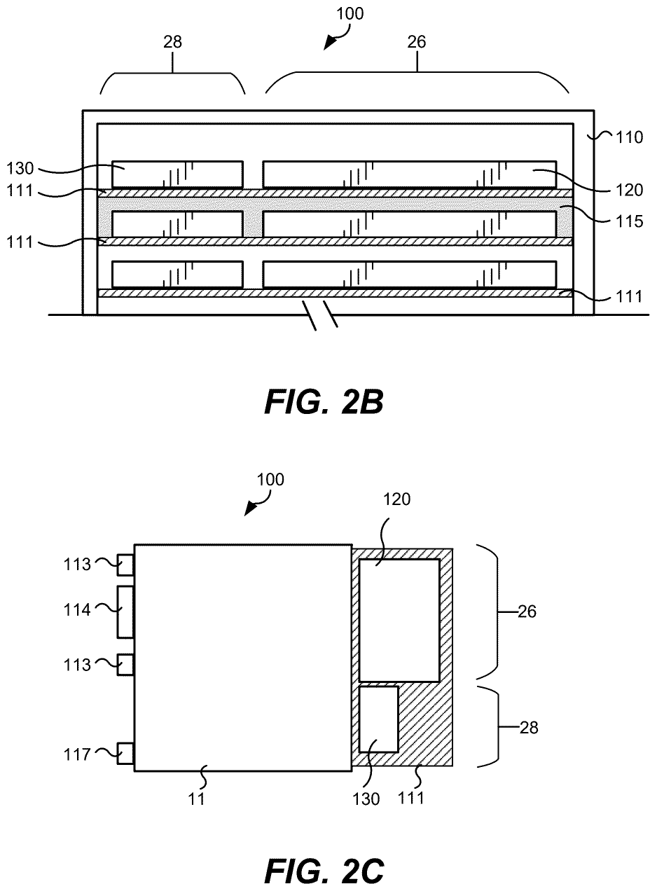

FIG. 2A illustrates a front view of an example IT rack 100, according to an implementation. FIG. 2B illustrates a zoomed in front view of a portion of an example IT rack 100 to show additional detail while omitting others for clarity, according to an implementation. Referring to FIG. 2B, a width of the inner portion of the enclosure body 110 may define the horizontal dimension of a rack slot 115. A horizontal dimension 26 may define an area in a rack slot 115 that is configured to receive a node 120. A horizontal dimension 28 may define an area in a rack slot 115 that is configured to receive a corresponding sidecar unit 130. A vertical dimension of a rack slot 115 may be defined by a slot support 111, such as a fixed or sliding rack shelf. In some examples, a sidecar unit 130 may be configured to be adjacent to a corresponding node 120 by being sized to fit within the horizontal dimension 28 and the vertical dimension of the rack slot 115. For example, sidecar unit 130 may include a body 136 that is generally sized and shaped to fit adjacent to a corresponding node 120 in a rack slot 115.

The sidecar unit 130 may be electrically coupled to the node 120 via an output connector 137. “Electrically coupled” and similar terms means that electrically conductive material from the coupled objects contact one another or otherwise transmit current between the objects. In some examples, the output connector 137 is a DC-DC PSU connector that takes in 400V+ as input (or other input voltage that is higher than the output voltage) and outputs 50V (or other voltage less than the input voltage). In some examples, the output connector 137 is a blind connector that blind mates to the node 120 through the side, such as after the removal from the IT rack 100. A blind mate is a type of electrical connection that is made without visually inspecting the contacts. In these implementations, the connector may include a push-to-connect connector, a crimp connector, a screw terminal, and/or other types of connectors that enable blind mating.

The sidecar unit 130 is “modular” because it can be decoupled from the corresponding node 120 and removed, such as via a blind connection. Further, the sidecar unit 130 may be modular because it can be reconnected with another node 120 for “plug-n-play” functionality.

FIG. 2C illustrates a top-down view of an example IT rack to co-location and adjacency of a node 120 and a modular sidecar power distribution unit 130 for improved serviceability, according to an implementation. As illustrated, a rack slot 115 is configured as a sliding rack shelf to aid in illustration. However, serviceability may still be improved for implementations in which a rack slot 115 is fixed, such as when a node 120 and a sidecar unit 130 are together or separately slid out of a rack slot 115 for servicing either or both.

FIG. 3 illustrates a top-down view of a rack slot 115 showing an example of a node 120 and a modular sidecar power distribution unit 130 that bridges power from a vertical bus bar 117 to the corresponding node 120 in the rack slot 115, according to an implementation. As illustrated, the sidecar unit 130 may receive, via an input connector 133, voltage input from the vertical bus bar 117, which receives the voltage input from the voltage distribution bus bar 140.

In some implementations, an input connector 133 may include a HVDC connector capable of receiving HVDC power from the vertical bus bar 117. Examples of an input connector 133 may include, without limitation, Anderson Powerpole connectors, T-connectors, Dry-type plug connectors, Bushings, COAX connectors, DIN-rail connectors, and Compression connectors.

The sidecar unit 130 may include a bridging module 131 that maintains the voltage input from the vertical bus bar 117. The bridging module 131 may include an electrically conductive material such as copper. The bridging module 131 may include a busbar, a contact relay, and/or other type of power bridge that can relay power.

For example, the bridging module 131 may receive 50V power provided from the voltage distribution bus bar 140 and provide the 50V power to the corresponding node 120. These examples may facilitate backward compatibility with nodes 120 or other equipment that use 50V or other legacy voltage. In some examples, the node 120 may include a converter 125 that converts the voltage received from the converter 135. For example, the converter 125 may convert 50V power (or other voltage) received from the sidecar unit 130 down to 12V (or other voltage lower than the received voltage).

In some implementations, a rack slot 115 may include a portion 119 that may house equipment, such as a power sources and/or other equipment to anticipate and be forward compatible with future features. For example, the portion 119 may be configured to house a local energy storage system 301. The local energy storage system 301 may be coupled to the input side (such as adjacent and/or parallel to the input connector 133) and/or output side (such as adjacent and/or parallel to the output connector 137) of the sidecar unit 130. A local energy storage system 301 may be a system that stores energy for the IT rack 100 and/or components thereof. The local energy storage system 301 may serve as backup power to some or all components, primary power to some or all components, supplemental power to some or all components, power conditioning to some or all components, power regulation to some or all components, and/or other power functions for some or all components of the IT rack 100. The local energy storage system 301 may be configurable based on particular requirements of the IT rack 100 and/or nodes thereof. For example, the local energy storage system 301 may include uninterruptable power supplies, batteries, flywheels, fuel cells, and/or other types of power storage system.

In some implementations, a sidecar unit 130 may include a power management system 132. The power management system 132 may include a combination of hardware and/or software that is configured to provide one or more power management functions. In some examples, the power management system may include a semiconductor-based microprocessor, a central processing unit (CPU), an application specific integrated circuit (ASIC), a field-programmable gate array (FPGA), and/or other suitable hardware. The power management system 132 may include or access a memory, which may be an electronic, magnetic, optical, or other physical storage device that includes or stores executable instructions. The memory may be, for example, Random Access memory (RAM), an Electrically Erasable Programmable Read-Only Memory (EEPROM), a storage device, an optical disc, and the like. The memory may be a non-transitory machine-readable storage medium, where the term “non-transitory” does not encompass transitory propagating signals.

The power management system 132 may provide one or more power distribution functions, one or more remote management functions, one or more environmental monitoring functions, overcurrent protection, and/or other management functions. Power distribution functions may include, for example, individual control of power outputs and power metering. Individual control of power output may be implemented if, for example, multiple outlets or other electrical connectors are provided. In these examples, specific electrical connections may be powered on or off. Power metering may include monitoring real-time power consumption data for each outlet or other output and/or for the entire sidecar unit 130, allowing for monitoring and optimization of power usage. Power monitoring such as voltage sensing may be based on sensor data from current sensors (not shown) transmitted to the power management system 132. Some or all of the power management functions may be facilitated through remote management functions that allow administrators or other so remotely control the sidecar unit 130. In some examples, the power management system 132 may be configured to provide alert notifications to administrators when one or more alert conditions are met, such as excessive power consumption, circuit breaker trips, or certain environmental conditions are met. Environmental monitoring may include, for example, temperature monitoring, humidity monitoring, and/or other monitoring of environmental conditions of the sidecar unit 130.

In some implementations, a sidecar unit 130 may include an output connector 134 that has the capability to provide power management data interfaces. Output connectors 134 for power management can vary depending on the specific application and device. For example, output connectors 134 may include barrel connectors, Universal Serial Bus (USB) connectors, DC power jacks, Deutsches Institut fur Normung (DIN) connectors, specialized connectors such as International Electrotechnical Commission (IEC) connectors, ANDERSON POWERPOLE connectors, MOLEX connectors, and others.

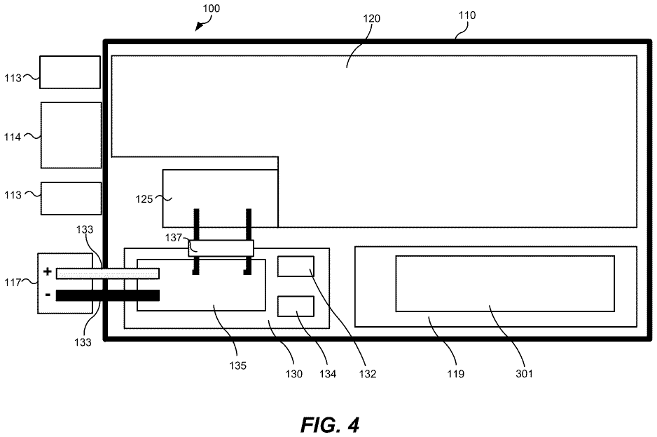

FIG. 4 illustrates a top-down view of a rack slot 115 showing an example of a node 120 and a sidecar unit 130 that converts power from a vertical bus bar 117, according to an implementation. In this example, the sidecar unit 130 may include a converter 135 that receives input power in a first voltage from the vertical bus bar 117, which may ultimately be provided from the voltage distribution bus bar 140. The converter 135 may then convert the input power from the first voltage to a second voltage and provide output power in the second voltage to the corresponding node 120. For example, the input power may be in the range of 400V, 800V, or other input voltage that is converted to a lower voltage such as 50V. In some examples, the node 120 may include a converter 125 that converts the voltage received from the converter 135. For example, the converter 125 may convert 50V power received from the sidecar unit 130 down to 12V.

In the foregoing examples of DC-to-DC conversion in which a higher DC voltage is converted to a lower DC voltage, the converter 135 may include DC-to-DC step-down converter. However, if the input power is AC, the converter 135 may include a transformer that converts AC voltage to DC voltage.

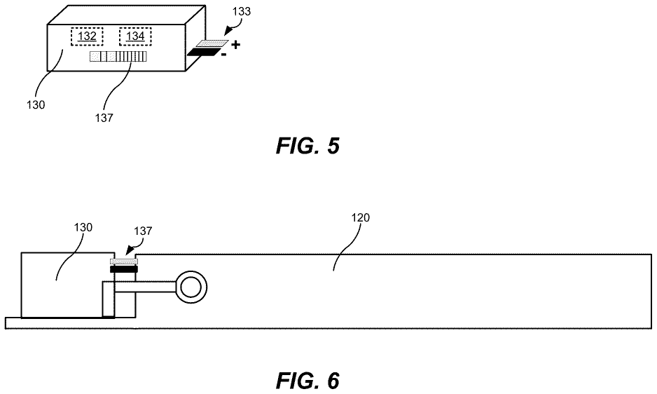

FIG. 5 illustrates a side perspective view of a sidecar unit 130, according to an implementation. FIG. 6 illustrates a front elevation view of an example of a sidecar unit 130 coupled to a node 120, according to an implementation. A sidecar unit 130 may be able to intake 50V and High Voltage DC (HVDC) input (such as 400V, 800V, and other voltages >400V) from the vertical bus bar 117, which may ultimately be provided from the voltage distribution bus bar 140. Each rack slot 115 may be configured to provide sufficient spacing to allow the sidecar unit 130 to sit adjacent to a node 120. Each node 120 may be removable through the front, allowing the sidecar unit 130 to be serviced when needed.

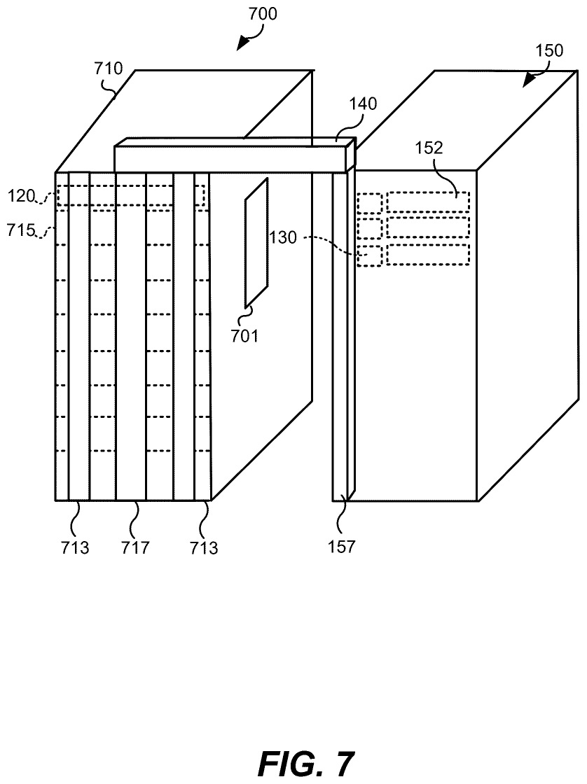

FIG. 7 illustrates an example of a sidecar unit 130 with a rack 700 with space limitations that prevent the sidecar unit 130 from being adjacent to a node 120, according to an implementation. Rack 700 may include an enclosure body 710. The enclosure body 110 may be made from a rigid material such as cold rolled steel, aluminum, stainless steel, and/or other materials that can suitably house or support the components of the IT rack 100. The enclosure body 110 may house or be coupled to a rack cooling manifold 713, a vertical bus bar 717, and/or other components. The rack cooling manifold 713 and vertical bus bar 717 are similar to the rack cooling manifold 113.

In some implementations, a vertical bus bar 717 provides power to a centralized power shelf system that generates 50V output. Through a vertical bus bar 717, the 50V is distributed to the nodes 120 within the rack 700. However, as the rack power infrastructure evolved to provide more power to the IT gears to support AI and Machine Learning application, the bottle neck to the infrastructure system becomes the power and thermal performance. 50V delivery may be unable to support power greater than 132 KW. By going to a minimum of 400V distribution, current may be 8× less due to law of physics and enable less use of copper or other conductive media to enable power distribution. Use of a sidecar unit 130 may address this power delivery shortcoming.

However, the enclosure body 710 may include a plurality of rack slots 715 that are each unable to house both a node 120 and a sidecar unit 130. Thus, instead of fitting the rack 700 with a sidecar unit 130 because of space limitations in a rack slot 715, one or more cutouts 701 may be made to a side of the rack 700 to enable blind and/or other connections between a node 120 and a corresponding sidecar unit 130. As illustrated, a sidecar unit 130 is housed within a power rack 150, although other configurations may be used so long as the sidecar unit 130 may be connected to a corresponding node 120 through a cutout 701.

### Description of Various Implementations

In some aspects, the techniques described herein relate to a sidecar unit, including: a body configured to be housed, together with and adjacent to a node, in a rack slot of an Information Technology (IT) rack; an input connector coupled to a vertical bus bar of the IT rack, the input connector configured to receive, from the vertical bus bar, input power having a first voltage; a converter that converts the input power from the first voltage to a second voltage, which is lower than the first voltage, to generate output power, or a bridging module that provides the output power in the first voltage; and an output connector coupled to the adjacent node in the rack slot, the output connector configured to provide the output power to the node, wherein the sidecar unit is configured to be releasable from the node to facilitate servicing the sidecar unit and/or the node.

In some aspects, the techniques described herein relate to a sidecar unit, wherein the sidecar unit includes the converter, the first voltage is at least in a range of 400V, and the converter is configured to generate the output power to have a second voltage lower than the first voltage.

In some aspects, the techniques described herein relate to a sidecar unit, wherein the second voltage is in a range of 50V.

In some aspects, the techniques described herein relate to a sidecar unit, wherein the sidecar unit includes the converter, the first voltage is at least in a range of 800V, and the converter is configured to generate the output power to have a second voltage lower than the first voltage.

In some aspects, the techniques described herein relate to a sidecar unit, wherein the sidecar unit includes the bridging module.

In some aspects, the techniques described herein relate to a sidecar unit, wherein the first voltage is in a range of 50V.

In some aspects, the techniques described herein relate to a sidecar unit, wherein the input power includes Direct Current (DC) power transmitted via a voltage distribution bus bar that is coupled to the vertical bus bar.

In some aspects, the techniques described herein relate to a sidecar unit, wherein the voltage distribution bus bar is coupled to one or more power distribution units of a power rack.

In some aspects, the techniques described herein relate to a sidecar unit, wherein the sidecar unit is sized to leave space in front of the sidecar unit in the rack slot for additional equipment.

In some aspects, the techniques described herein relate to a sidecar unit, further including a power management system that is configured to execute one or more power management functions.

In some aspects, the techniques described herein relate to a voltage distribution system, including: an Information Technology (IT) rack including: an enclosure body having a vertical bus bar and a plurality of rack slots, the vertical bus bar being configured to receive power from a voltage distribution bus bar, each rack slot from among the plurality of rack slots configured to house a respective node and a corresponding sidecar unit for the respective node; a sidecar unit including: a body configured to be housed, together with and adjacent to a node, in a rack slot of the IT rack; an input connector coupled to the vertical bus bar, the input connector configured to receive, from the vertical bus bar, input power having a first voltage; a converter that converts the input power from the first voltage to a second voltage, which is lower than the first voltage, to generate output power, or a bridging module that provides the output power in the first voltage; an output connector coupled to the adjacent node in the rack slot, the output connector configured to provide the output power to the corresponding node, wherein the sidecar unit is configured to be releasable from the node to facilitate servicing the sidecar unit and/or the node.

In some aspects, the techniques described herein relate to a voltage distribution system, wherein the sidecar unit includes the converter, the first voltage is at least in a range of 400V, and the converter is configured to generate the output power to have a second voltage lower than the first voltage.

In some aspects, the techniques described herein relate to a voltage distribution system, wherein the second voltage is in a range of 50V.

In some aspects, the techniques described herein relate to a voltage distribution system, wherein the sidecar unit includes the converter, the first voltage is at least in a range of 800V, and the converter is configured to generate the output power to have a second voltage lower than the first voltage.

In some aspects, the techniques described herein relate to a voltage distribution system, wherein the sidecar unit includes the bridging module.

In some aspects, the techniques described herein relate to a voltage distribution system, wherein the first voltage is in a range of 50V.

In some aspects, the techniques described herein relate to a voltage distribution system, wherein the sidecar unit is sized to leave space in front of the sidecar unit in the rack slot for additional equipment.

In some aspects, the techniques described herein relate to a voltage distribution system, wherein the sidecar unit further includes a power management system that is configured to execute one or more power management functions.

In some aspects, the techniques described herein relate to a voltage distribution system, including: a power rack including: one or more power supplies that provide High Voltage Direct Current (HVDC) power in a range of at least 400V; and a first vertical bus bar electrically coupled to the one or more power supplies and to a voltage distribution bus bar, the first vertical bus bar electrically transmitting the HVDC power from the one or more power supplies to the voltage distribution bus bar; and an Information Technology (IT) rack including: a plurality of rack slots, each rack slot configured to receive a node and corresponding sidecar unit; and a second vertical bus bar electrically coupled to the first vertical bus bar to receive input power from the first vertical bus bar and distribute the input power to one or more equipment housed in at least one of the plurality of rack slots.

In some aspects, the techniques described herein relate to a voltage distribution system, further including: a sidecar unit including: a body configured to be housed, together with and adjacent to a node, in a rack slot of the IT rack; an input connector coupled to the second vertical bus bar, the input connector configured to receive, from the second vertical bus bar, input power having a first voltage; a converter that converts the input power from the first voltage to a second voltage, which is lower than the first voltage, to generate output power; and an output connector coupled to the adjacent node in the rack slot, the output connector configured to provide the output power to the corresponding node, wherein the sidecar unit is configured to be releasable from the node to facilitate servicing the sidecar unit and/or the node.

Throughout the disclosure, the terms “a” and “an” may be intended to denote at least one of a particular element. As used herein, the term “includes” means includes but not limited to, the term “including” means including but not limited to. The term “based on” means based at least in part on. The term “in the range of” means that those having ordinary skill in the art would recognize that the stated value will have substantially similar values that would be interchangeable. For example, a voltage in the range of 400V means that the voltage can deviate from 400V without substantially altering the characteristics of the current, the power transmitting device, or the power receiving device, as would be appreciated by those having ordinary skill in the art.

The terms “first”, “second”, “third,” “given” and so on, if used in claims, are used to distinguish or otherwise identify, and not to show a sequential or numerical limitation. Those skilled in the art will recognize that the present teachings are amenable to a variety of modifications, deletions, and/or enhancements. For example, although the implementation of various components described above may be embodied in a hardware device, it may also be implemented as a software only solution—such as an installation on an existing server. In addition, the conversation management techniques as disclosed herein may be implemented as a firmware, firmware and software combination; firmware and hardware combination; or a hardware, firmware, and software combination.

The description and the drawings are not intended to limit the present techniques to the particular form disclosed, but to the contrary, the intention is to cover all modifications, equivalents, and alternatives falling within the spirit and scope of the present techniques as defined by claims. Further modifications and alternative embodiments of various aspects of the techniques will be apparent to those skilled in the art in view of this description. Accordingly, this description and the drawings are to be construed as illustrative only and are for the purpose of teaching those skilled in the art the general manner of carrying out the present techniques. It is to be understood that the forms of the present techniques shown and described herein are to be taken as examples of embodiments. Elements and materials may be substituted for those illustrated and described herein, parts and processes may be reversed or omitted, and certain features of the present techniques may be utilized independently, all as would be apparent to one skilled in the art after having the benefit of this description of the present techniques. Changes may be made in the elements described herein without departing from the spirit and scope of the present techniques as described in claims.

This written description uses examples to disclose the embodiments, including the best mode, and to enable any person skilled in the art to practice the embodiments, including making and using any devices or systems and performing any incorporated methods. The patentable scope of the disclosure is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A sidecar unit, comprising:
a body configured to be housed, together with and adjacent to a node, in a rack slot of an Information Technology (IT) rack;
an input connector coupled to a vertical bus bar of the IT rack, the input connector configured to receive, from the vertical bus bar, input power having a first voltage;
a converter that converts the input power from the first voltage to a second voltage, which is lower than the first voltage, to generate output power, or a bridging module that provides the output power in the first voltage; and
an output connector coupled to the adjacent node in the rack slot, the output connector configured to provide the output power to the node,
wherein the sidecar unit is configured to be releasable from the node to facilitate servicing the sidecar unit and/or the node.

2. The sidecar unit of claim 1, wherein the sidecar unit includes the converter, the first voltage is at least in a range of 400V, and the converter is configured to generate the output power to have a second voltage lower than the first voltage.

3. The sidecar unit of claim 2, wherein the second voltage is in a range of 50V.

4. The sidecar unit of claim 1, wherein the sidecar unit includes the converter, the first voltage is at least in a range of 800V, and the converter is configured to generate the output power to have a second voltage lower than the first voltage.

5. The sidecar unit of claim 1, wherein the sidecar unit includes the bridging module.

6. The sidecar unit of claim 5, wherein the first voltage is in a range of 50V.

7. The sidecar unit of claim 1, wherein the input power comprises Direct Current (DC) power transmitted via a voltage distribution bus bar that is coupled to the vertical bus bar.

8. The sidecar unit of claim 7, wherein the voltage distribution bus bar is coupled to one or more power distribution units of a power rack.

9. The sidecar unit of claim 1, wherein the sidecar unit is sized to leave space in front of the sidecar unit in the rack slot for additional equipment.

10. The sidecar unit of claim 1, further comprising a power management system that is configured to execute one or more power management functions.

11. A voltage distribution system, comprising:
an Information Technology (IT) rack comprising:
an enclosure body having a vertical bus bar and a plurality of rack slots, the vertical bus bar being configured to receive power from a voltage distribution bus bar, each rack slot from among the plurality of rack slots configured to house a respective node and a corresponding sidecar unit for the respective node; and
a sidecar unit comprising:
a body configured to be housed, together with and adjacent to a node, in a rack slot of the IT rack;
an input connector coupled to the vertical bus bar, the input connector configured to receive, from the vertical bus bar, input power having a first voltage;
a converter that converts the input power from the first voltage to a second voltage, which is lower than the first voltage, to generate output power, or a bridging module that provides the output power in the first voltage; and
an output connector coupled to the adjacent node in the rack slot, the output connector configured to provide the output power to the corresponding node,
wherein the sidecar unit is configured to be releasable from the node to facilitate servicing the sidecar unit and/or the node.

12. The voltage distribution system of claim 11, wherein the sidecar unit includes the converter, the first voltage is at least in a range of 400V, and the converter is configured to generate the output power to have a second voltage lower than the first voltage.

13. The voltage distribution system of claim 12, wherein the second voltage is in a range of 50V.

14. The voltage distribution system of claim 11, wherein the sidecar unit includes the converter, the first voltage is at least in a range of 800V, and the converter is configured to generate the output power to have a second voltage lower than the first voltage.

15. The voltage distribution system of claim 14, wherein the sidecar unit includes the bridging module.

16. The voltage distribution system of claim 15, wherein the first voltage is in a range of 50V.

17. The voltage distribution system of claim 11, wherein the sidecar unit further comprises a power management system that is configured to execute one or more power management functions.

18. The voltage distribution system of claim 11, further comprising:
a local energy storage system to be housed in a portion of at least one rack slot, wherein the local energy storage system is coupled in parallel to the input connector or the output connector of the sidecar unit.

19. A voltage distribution system, comprising:
a power rack comprising:
one or more power supplies that provide High Voltage Direct Current (HVDC) power in a range of at least 400V; and
a first vertical bus bar electrically coupled to the one or more power supplies and to a voltage distribution bus bar, the first vertical bus bar electrically transmitting the HVDC power from the one or more power supplies to the voltage distribution bus bar;
an Information Technology (IT) rack comprising:
a plurality of rack slots, each rack slot configured to receive a node and corresponding sidecar unit; and
a second vertical bus bar electrically coupled to the first vertical bus bar to receive input power from the first vertical bus bar and distribute the input power to one or more equipment housed in at least one of the plurality of rack slots; and
a sidecar unit comprising:
a body configured to be housed, together with and adjacent to a node, in a rack slot of the IT rack;
an input connector coupled to the second vertical bus bar, the input connector configured to receive, from the second vertical bus bar, input power having a first voltage;
a converter that converts the input power from the first voltage to a second voltage, which is lower than the first voltage, to generate output power; and
an output connector coupled to the adjacent node in the rack slot, the output connector configured to provide the output power to the corresponding node, wherein the sidecar unit is configured to be releasable from the node to facilitate servicing the sidecar unit and/or the node.

20. The voltage distribution system of claim 19, wherein the sidecar unit is sized to leave space in front of the sidecar unit in the rack slot for additional equipment.
